(19) United States
(12) Patent Application Publication
(10) Pub. No.: US 2003/0224542 A1
(43) Pub. Date: Dec. 4, 2003

(54) Method for making multi-chip packages and single chip packages simultaneously and structures from thereof

(75) Inventor: Wen-Chun Liu, Kaohsiung (TW)

Correspondence Address: BRUCE H. TROXELL, SUITE 1404, 5205 LEESBURG PIKE, FALLS CHURCH, VA, 22041, US

(73) Assignee: Walsin Advanced Electronics LTD

(21) Appl. No.: 10/156,021

(22) Filed: May 29, 2002

(51) Int. Cl. H01L 21/66; H01L 21/44; H01L 21/48

(52) U.S. Cl. 438/15; 438/126; 438/613

(57) ABSTRACT

A method for making multi-chip packages and single-chip packages simultaneously and structures thereof are provided. The method comprises the steps of chip-attaching, electrically connecting, encapsulating and electrically testing, all the step are executed on a package substrate with channel holes. The package substrate is selectively cut so as to form multi-chip packages and single-chip packages simultaneously. Each semiconductor package has a plurality of coplanar wiring substrates defined by the channel holes and selective cutting lines. A space between two adjacent wiring substrates is formed from corresponding channel hole and is filled with the isolating encapsulant so as to perform cushioning effect for reducing thermal stress and to improve the structure strength of the package assembly.

### FIELD OF THE INVENTION

The present invention is relating to a method for making multi-chip packages, particularly to a method for making multi-chip packages and single chip packages simultaneously and structures formed from the method.

### BACKGROUND OF THE INVENTION

Conventionally, MCP (Multi-Chip Package) includes several chips combined with an encapsulating package for enhancing memory capacity or increasing functional performances. It is familiar that the chips for the multi-chip package has to be electrically tested prior to packaging procedures in order to pick out KGD (Known Good Die), then several of the KGD (Known Good Die) should be packaged to form a multi-chip semiconductor package. If known good dies are not adopted for conventional multi-chip packaging method, a whole multi-chip semiconductor package may not work due to one included defective chip, so as to cause quite high reject rate. In addition to electrical test of bare chips, multi-chip semiconductor packages ought to be electrically tested once after packaging to ensure packaging quality. However, the steps of electrical test should be decreased as less as possible for reducing cost in accordance with the advancement for manufacturing process of semiconductor chip and the trend for low price of chip.

A stack type multi chip package had been brought up from European Patent No. EP 1061579, which comprises a chip with larger size attached on a substrate, and a chip with smaller size attached on the chip with larger size. The chip with smaller size is electrically connected with the substrate by metal bonding wires and a wiring layer on the chip with larger size. However, the stack type multi-chip package also ought to use KGD during manufacture in order to avoid high reject rate. Due to the quite different chips in size and function, a method for making the multi-chip package is not applied to produce multi-chip package with same chips.

### SUMMARY

It is a first object of the present invention to provide a method for making semiconductor packages with a plurality of co-planar wiring substrates. The co-planar wiring substrates in each semiconductor package are formed by means of channel holes of a package substrate and selective cutting lines. A space between two adjacent wiring substrates is formed from the corresponding channel hole, and is filled with an isolating encapsulant so as to perform cushioning effect for reducing thermal stress and to improve structure strength of the package assembly.

It is a second object of the present invention to provide a method for making multi-chip packages and single chip packages simultaneously, which is to electrically test chips on a package substrate before singulating, and to selectively cut the package substrate for elastically manufacturing multi-chip packages and single-chip packages. It is especially suitable for making the multi-chip package from unknown good chips.

It is a third object of the present invention is to provide a semiconductor package, wherein there is a space between two adjacent coplanar wiring substrates. The space is filled with an isolating encapsulant so as to perform cushioning effect for reducing thermal stress and to improve structure strength of the package assembly.

According to the method for multi-chip package of the present invention, it comprises the steps of chip-attach, electrically connecting, forming isolating encapsulant, and electrically testing, which are executed on a package substrate with channel holes. Then, the package substrate is selectively cut according to the testing result to form multi-chip packages or single-chip packages. A plurality of coplanar wiring substrates within a semiconductor package are defined by the channel holes and the cutting lines of package substrate. A space between two adjacent wiring substrates is formed from the corresponding channel holes, and is filled with an isolating encapsulant so as to perform cushioning effect for reducing thermal stress and to improve the structure strength of the package assembly. It is preferable to form outer terminals such as solder balls or conductive bumps on the package substrate before selectively dicing.

According to the semiconductor package of the present invention, it comprises a plurality of wiring substrates corresponding to each chip. The wiring substrates are formed on a same plane. And a space formed between two adjacent wiring substrates is filled with the isolating encapsulant so as to perform cushioning effect for reducing thermal stress and improve bonding of wiring substrates. It is better that a plurality of gaps are formed around the wiring substrates and filled with isolating encapsulant.

### DESCRIPTION OF THE DRAWINGS

FIG. 1 is a process flow in accordance with the method for making multi-chip package of the present invention.

FIG. 2a shows a first surface of a provided package substrate in accordance with the method for making multi-chip package of the present invention.

FIG. 2b shows a second surface of the package substrate in the step of chip-attaching in accordance with the method for making multi-chip package of the present invention.

FIG. 2c shows the second surface of the package substrate in the step of electrically connecting in accordance with the method for making multi-chip package of the present invention.

FIG. 2d shows the second surface of the package substrate in the step of forming isolating encapsulant in accordance with the method for making multi-chip package of the present invention.

FIG. 2e is a cross-sectional view of the package substrate in the step of electrically testing in accordance with the method for making multi-chip package of the present invention.

FIG. 2f shows the second surface of the package substrate in the step of selective cutting in accordance with the method for making multi-chip package of the present invention.

FIG. 3 is a cross-sectional view of a formed semiconductor package in accordance with the method for making multi-chip package of the present invention.

FIG. 4 is a cross-sectional view of a semiconductor package in accordance with another embodiment of the present invention.

### DETAILED DESCRIPTION OF THE PRESENT INVENTION

Referring to the FIGS, the present invention will be described by means of the embodiments below.

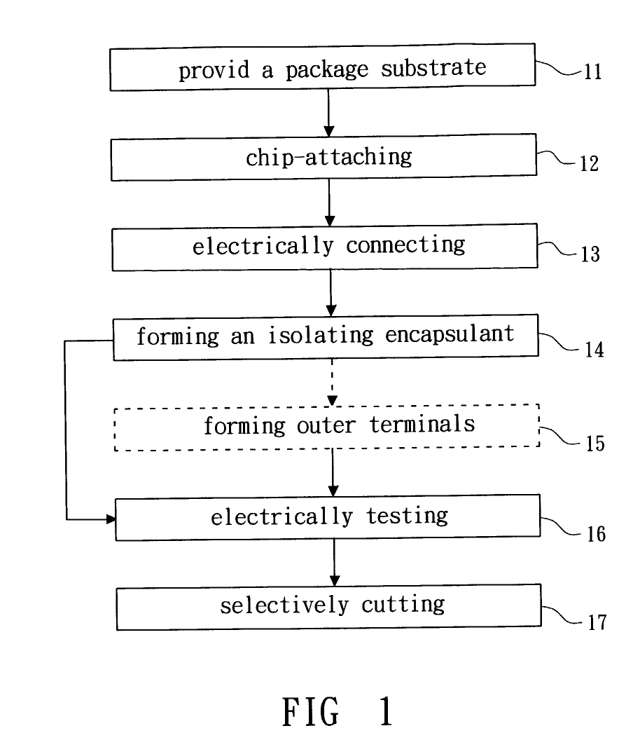

As shown in FIG. 1, according to the present invention the method for making multi-chip package comprises the steps of “providing a package substrate” 11, “chip-attaching” 12, “electrically connecting” 13, “forming an isolating encapsulant” 14, “forming outer terminals” 15, “electrically testing” 16, and “selectively cutting” 17.

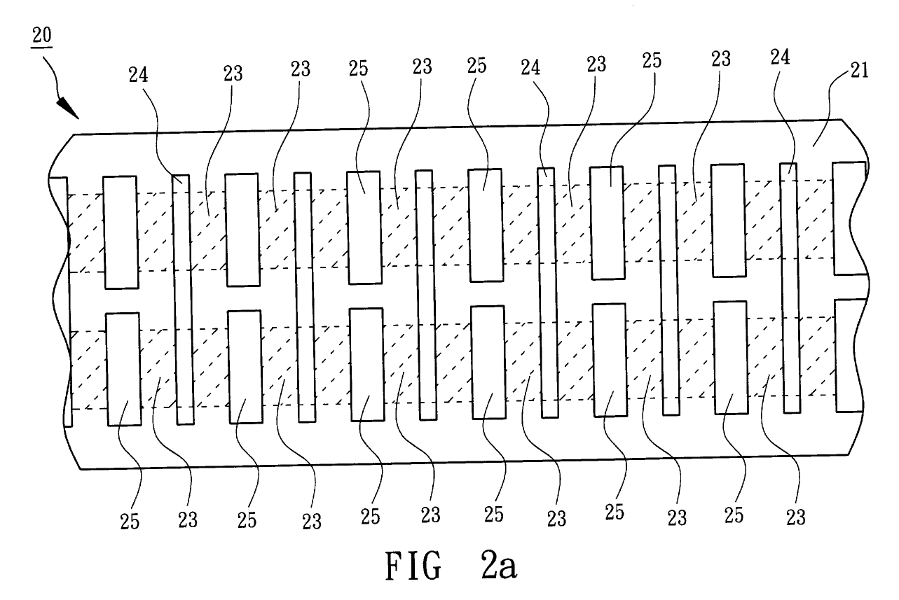

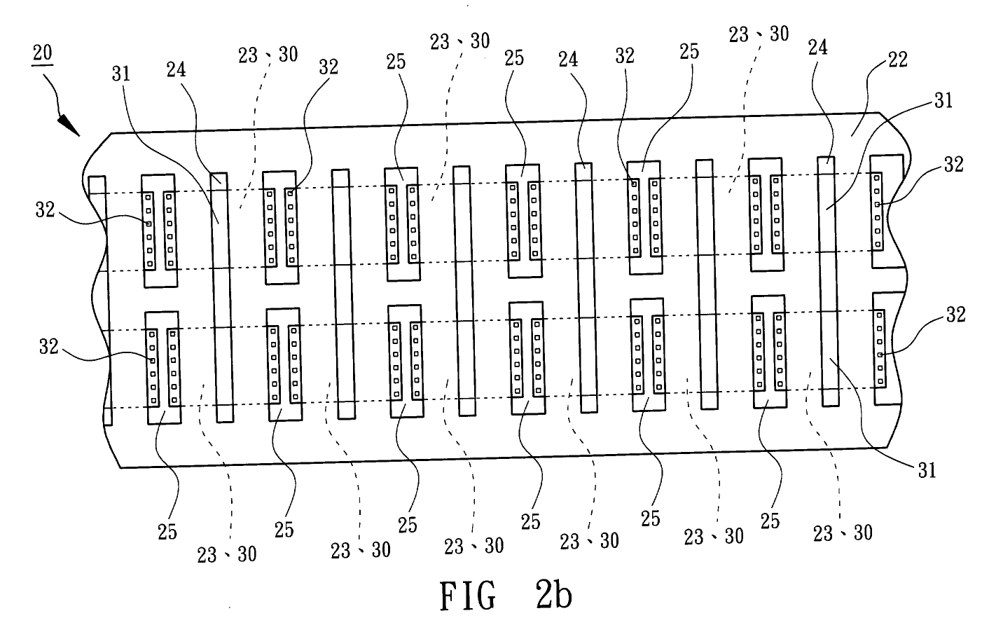

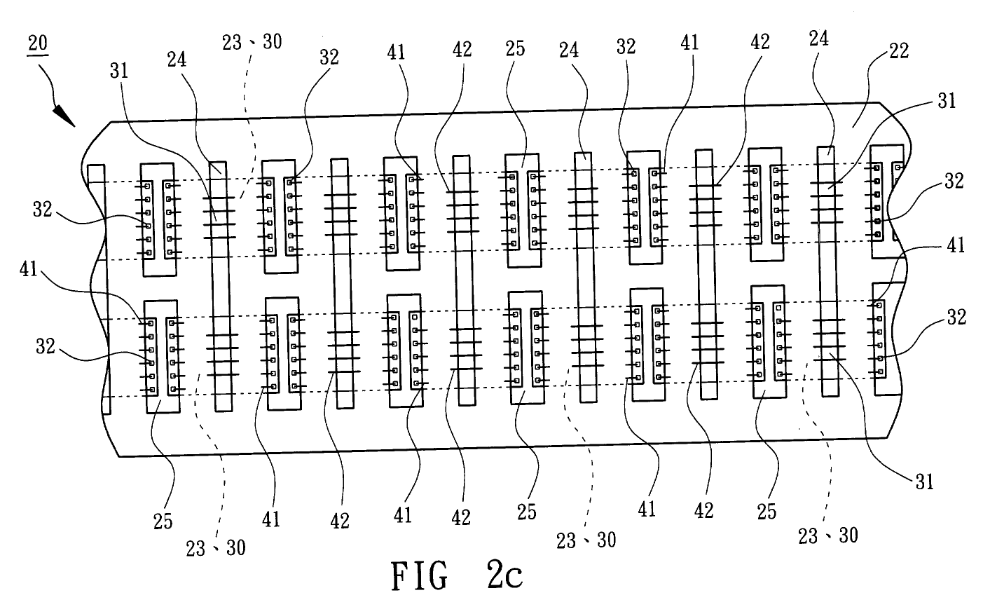

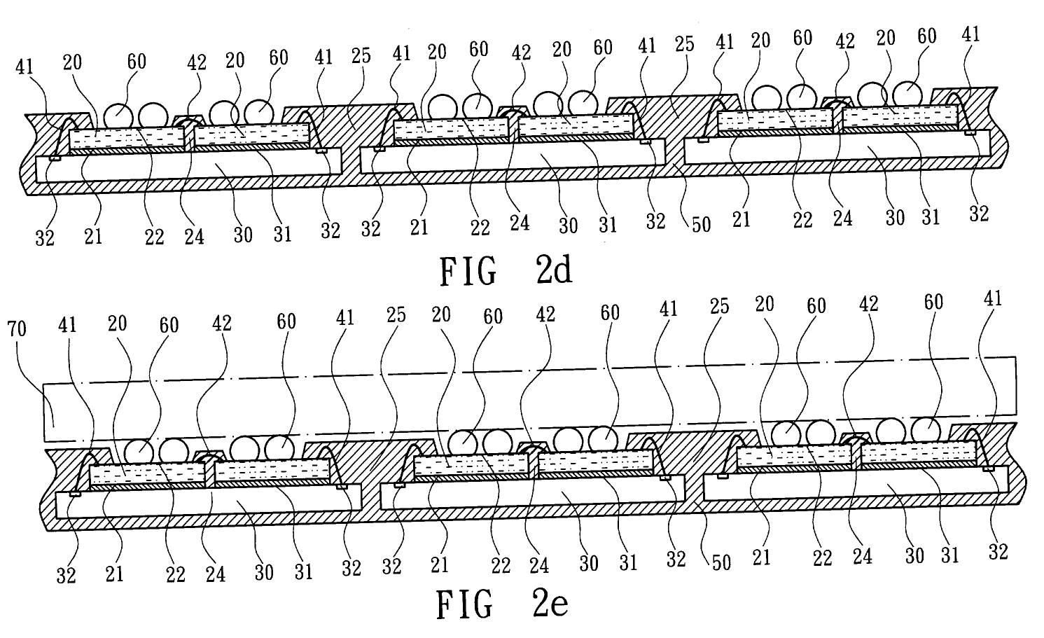

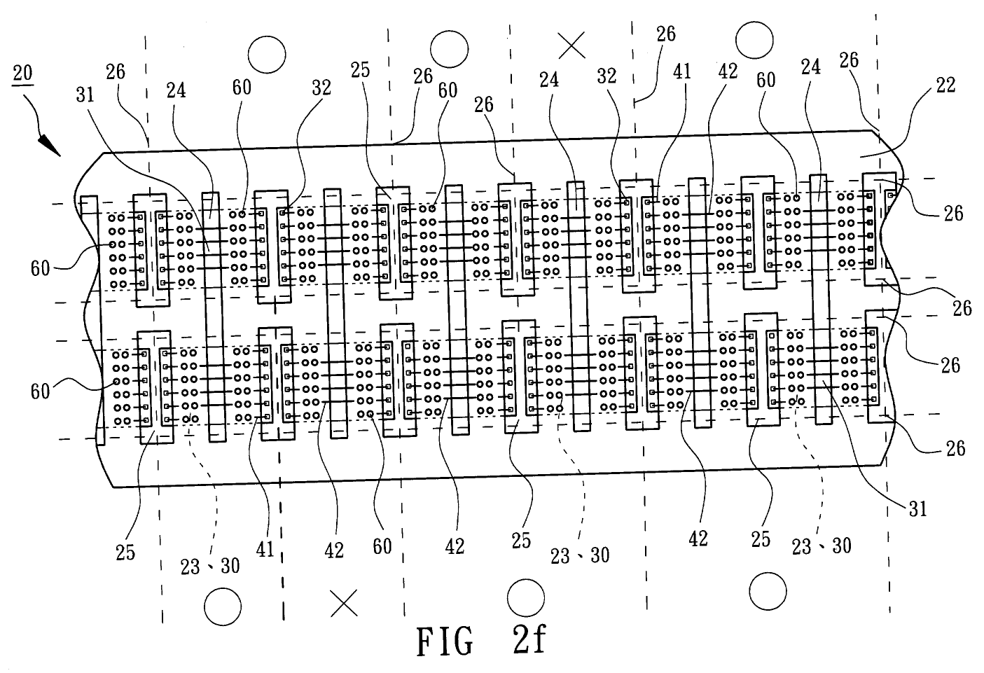

Firstly in the step of “providing a package substrate” 11, as shown in FIG. 2a, a package substrate 20 is prepared. The package substrate 20 has wiring pattern of single or multi layers and is made from FR-4, FR-5, or BT resin, etc which includes resin materials reinforced with glass fiber. Alternatively, the package substrate 20 is a co-fired ceramic wiring board or even a polyimide flexible film with wiring layer. The package substrate 20 has a first surface 21 forming a plurality of defined chip-attaching areas 23 for attaching several same or different chips, and a second surface 22 (as shown in FIG. 2d). The package substrate 20 has a plurality of openings 25 at the two sides of each chip-attaching area 23. A channel hole 24 extends through each chip-attaching area 23.

In the step of “chip-attach” 12, an adhesive is formed on the chip-attaching areas 23 of the package substrate 20 by printing in liquid phase or sticking at tape type. Then a plurality of corresponding same chips 30 are attached on the chip-attaching areas 23 (first surface 21 of the package substrate 20). The chips 30 are untested chip directly diced from a wafer or tested KGDs. As shown in FIGS. 2b and 2d, each chip 30 has an active surface 31 and a plurality of bonding pads 32 on peripheries of the active surface 31. While the active surface 31 of each chip 30 is attached on corresponding chip-attaching area 23, the bonding pads 32 of the chip 30 are exposed at the openings 25. It is usual that the chip 30 can be a memory chip, microprocessor, logic chip or other chips such as DRAM, SRAM, SDRAM, ROM, EPROM, flash, Rambus or DDR, etc. Preferably, the same chips 30 are SRAM (Static Random Access Memory).

In the step of “electrically connecting” 13, as shown in FIG. 2c, the bonding pads 32 of chips 30 are electrically connected with the package substrate 20 by means of first bonding wires 41 formed by wire-bonding or TAB (Tape Automated Bonding) leads. It is better that at least a second bonding wire 42 formed across the channel hole 24 electrically connects with the package substrate 20 internally.

In the step of “forming an isolating encapsulant” 14, as shown in FIG. 2d, an isolating encapsulant 50 is formed by molding technique, such as transfer molding or injection molding. The isolating encapsulant 50 includes electrically-isolating thermosetting resin. In this embodiment, the isolating encapsulant 50 seals chips 30 and fills the channel holes 24 and openings 25 so as to seal the bonding wires 41, 42 and chips 30.

If necessary, a step of “forming outer terminals” 15 is executed after executing the step of “forming an isolating encapsulant” 14. As shown in FIG. 2d, a plurality of outer terminals 60, such as solder balls of lead-tin or conductive bumps, are formed on the second surface 22 of the package substrate 20 by printing, electroplating or bonding plant method. The step of “forming outer terminals” 15 also can be executed after executing the step of “electrically testing” 16.

In the step of “electrically testing” 16, as shown in FIG. 2e, a test probe card 70 installed in test equipment is applied to contact the outer terminals 60 of the package substrate 20 to electrically couple with the package substrate 20 and test equipment for electrically testing the chips 30 and internally electrical connections (such as bonding wires 41, 42 and metal traces of package substrate 20). Another test measuring method is that a test terminal is additionally extended from the package substrate 20 for electrical contacting of a test probe needle.

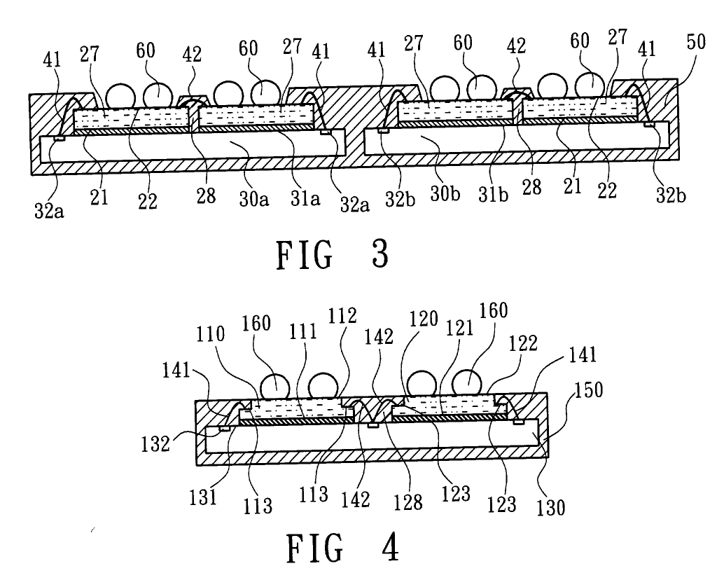

In the step of “selectively cutting” 17, as shown in FIG. 2f, according to test result of “electrically testing” 16, a plurality of selective cutting lines 26 are defined on the package substrate 20. The good chips 30 which are tested pass(including both electrical connection and package are good) are showed in “O” of FIG. 2f. The bad chips 30 which are tested fail (including defective package or electrical connection) are showed in “X” of FIG. 2f. The package substrate 20 is cut vertically and horizontally along the selective cutting lines 26 for manufacturing good multi-chip (double-chip or more) semiconductor packages and single-chip semiconductor packages simultaneously. Some horizontally selective cutting lines 26 are set between the chip-attaching areas 23 and passing through portion of the channel holes 24 which extends over the corresponding chip-attaching areas 23. After cutting, several coplanar wiring substrates 27 in a semiconductor package (as shown in FIG. 3) are formed by the channel holes 24 and selective cutting lines 26 of the package substrate 20, which are corresponding to passed chip 30a, 30b and are integrated by the isolating encapsulant 50.

The method mentioned above is to manufacture multi-chip (double-chip) semiconductor package and single-chip semiconductor package from untested bare chips or known good chips for decreasing manufacturing cost. Among the chips 30 mentioned above, two adjacent good chips 30a, 30b passing through the “electrically testing” step 16 form a semiconductor package shown in FIG. 3. The first chip 30a in the semiconductor package has an active surface 31a and a plurality of bonding pads 32a around the active surface 31a. The second chip 30b is same as the first chip 30a and also has an active surface 31b and a plurality of bonding pads 32b around the active surface 31b. The active surface 31a of the first chip 30a and the active surface 31b of the second chip 30b are coplanar attached with a plurality of wiring substrates 27 corresponding to each chip 30a and 30b respectively. Each wiring substrate 27 has a first surface 21 and a second surface 22. All the first surfaces 21 are coplanar and adhered on the active surfaces 31a, 31b of the corresponding chips 30a, 30b, without covering the bonding pads 32a, 32b of the chips 30a, 30b. A space 28 between two adjacent wiring substrates 27 is formed from corresponding channel hole 24 of the package substrate 20 and fills with isolating encapsulant 50 for reducing thermal stress during surface mounting and improving the structure strength of the package assembly. Moreover, The isolating encapsulant 50 seals the chips 30a, 30b and the bonding wires 41, 42.

According to another embodiment of the present invention, as shown in FIG. 4, the semiconductor package is a CSP (Chip Scale Package) manufactured by the semiconductor manufacturing method mentioned above. The semiconductor package comprises a semiconductor chip 130 having an active surface 131 and a plurality of bonding pads 132 on the active surface 131. A first wiring substrate 110 and a second wiring substrate 120 are adhered on the active surface 131 of chip 130. A first surface 111 of the first wiring substrate 110 and a first surface 121 of the second wiring substrate 120 are formed on same plane and attached on the active surface 131 of the chip 130 without covering the bonding pads 132 of the chip 130. There is a space 128 formed between the first wiring substrate 110 and the second wiring substrate 120. In this embodiment, gaps 113, 123 in ladder-like shape are respectively formed around the first wiring substrate 110 and the second wiring substrate 120 for plane plate molding. First bonding wires 141 electrically connect the bonding pads 132 around the chip 130 with the wiring substrates 110, 120. Second bonding wires 142 pass through the space 128 and electrically connect the bonding pads 132 at the center of the chip 130 with the wiring substrates 110, 120. An isolating encapsulant 150 is filled in the space 128 and the gaps 113, 123 and seals the first bonding wires 141 and the second bonding wires 142. A plurality of outer terminals 160 are formed on the second surfaces 112, 122 of the wiring substrates 110, 120, such as solder balls or conductive bumps for surface mounting.

The above description of embodiments of this invention is intended to be illustrative and not limiting. Other embodiments of this invention will be obvious to those skilled in the art in view of the above disclosure.

What is claimed is:

1. A method for making semiconductor packages comprising the steps of:
providing a package substrate, the package substrate having a first surface, a second surface and a plurality of channel holes, wherein a plurality of chip-attaching areas are defined on the first surface and the channel holes extend over the corresponding chip-attaching areas;
attaching a plurality of chips onto the chip-attaching areas so that active surfaces of the chips are adhered on the first surface of the package substrate;
electrically connecting the chips with the package substrate;
forming an isolating encapsulant filling the channel holes;
electrically testing the chips on the package substrate; and
selectively cutting the package substrate according to the test result, wherein a plurality of selective cutting lines pass through portions of the channel holes extending over the chip-attaching areas so as to form semiconductor packages each having a plurality of coplanar wiring substrates assembling with the isolating encapsulant.

2. The method for making semiconductor packages in accordance with claim 1, wherein the chips are the same.

3. The method for making semiconductor packages in accordance with claim 1, further comprising a step of forming outer terminals on the second surface of the package substrate.

4. The method for making semiconductor packages in accordance with claim 1, wherein the isolating encapsulant is filled in the channel holes and seals the chips in the step of forming isolating encapsulant.

5. The method for making semiconductor packages in accordance with claim 1, wherein each chip has a plurality of bonding pads on the peripheries of the first surface in the step of chip-attaching.

6. The method for making semiconductor packages in accordance with claim 1, wherein at least a bonding wire crosses through the channel hole, and has two ends bonding on the package substrate in the step of electrically connecting.

7. A semiconductor package comprising:
a first chip having an active surface and a plurality of bonding pads on the active surface;
a second chip having an active surface and a plurality of bonding pads on the active surface, wherein the active surface of the first chip and the active surface of the second chip are coplanar;
a plurality of wiring substrates, each having a first surface and a second surface, wherein the first surfaces are coplanar and attached on the active surfaces of the corresponding chips without covering the bonding pads of the chips, and a space is formed between two adjacent wiring substrates;
a plurality of electrically connecting devices electrically connecting the bonding pads of the chips with the corresponding wiring substrates; and
an isolating encapsulant sealing the electrically connecting devices.

8. The semiconductor package in accordance with claim 7, wherein the isolating encapsulant fills the space.

9. The semiconductor package in accordance with claim 7, wherein the isolating encapsulant seals the first chip and the second chip.

10. The semiconductor package in accordance with claim 7, further comprising a plurality of solder balls formed on the second surfaces of the wiring substrates.

11. The semiconductor package in accordance with claim 7, wherein a plurality of gaps are formed around the wiring substrates.

12. The semiconductor package in accordance with claim 7, further comprising at least one second electrically connecting device electrically connecting two adjacent wiring substrates through the space.

13. The semiconductor package in accordance with claim 7, further comprising second electrically connecting devices electrically connecting the wiring substrates with the corresponding chips through the space.

14. A semiconductor package comprising:
at least a chip having an active surface and a plurality of bonding pads on peripheries of the active surface;
a plurality of wiring substrates, each having a first surface and a second surface, wherein the first surfaces are coplanar and attached on the active surface of the chip without covering the bonding pads of the chip, and a space is formed between two adjacent wiring substrates;
a plurality of electrically connecting devices electrically connecting the bonding pads of the chip with the wiring substrates; and
an isolating encapsulant sealing the electrically connecting devices.

15. The semiconductor package in accordance with claim 14, wherein the isolating encapsulant fills the space.

16. The semiconductor package in accordance with claim 14, wherein the isolating encapsulant seals the chip.

17. The semiconductor package in accordance with claim 14, further comprising a plurality of solder balls formed on the second surfaces of the wiring substrates.

18. The semiconductor package in accordance with claim 14, wherein a plurality of gaps are formed around the wiring substrates.

19. The semiconductor package in accordance with claim 14, further comprising at least one second electrically connecting devices electrically connecting two adjacent wiring substrates through the space.

20. The semiconductor package in accordance with claim 14, further comprising second electrically connecting devices electrically connecting the chips with the wiring substrates through the space.
